(19) United States
(12) Patent Application Publication
(10) Pub. No.: US 2016/0254424 A1
(43) Pub. Date: Sep. 1, 2016

(54) OPTOELECTRONIC LIGHTING DEVICE

(71) Applicant: OSRAM Opto Semiconductors GmbH, Regensburg (DE)

(72) Inventors: Michael Zitzlsperger, Regensburg (DE); Matthias Lermer, Regensburg (DE); Roland Fischl, Regensburg (DE)

(21) Appl. No.: 15/054,585

(22) Filed: Feb. 26, 2016

(30) Foreign Application Priority Data
Feb. 26, 2015 (DE) 10 2015 102 785.2

(51) Int. Cl. H01L 33/54; H01L 33/62; H01L 33/44; H01L 33/08; H01L 33/60

(52) U.S. Cl. CPC H01L 33/54; H01L 33/08; H01L 33/60; H01L 33/44; H01L 33/62; H01L 2933/005; H01L 2933/0058; H01L 2933/0025; H01L 2933/0066

(57) ABSTRACT

A method of producing an optoelectronic lighting device includes providing a carrier on which is arranged at least one light-emitting diode including a surface that emits light during operation of the light-emitting diode, carrying out an injection molding process to encapsulate the light-emitting diode by molding as far as the light-emitting surface such that a molded housing is formed within which the light-emitting diode is encapsulated by molding, wherein the light-emitting surface remains at least partly free, shaping a reflector that reflects light emitted by the light-emitting surface during the injection molding process such that the reflector is formed integrally with the housing, at least partly masking the light-emitting surface, coating the reflector with a light-reflecting layer after the masking, and demasking the light-emitting surface after the coating.

### TECHNICAL FIELD

This disclosure relates to methods of producing optoelectronic lighting devices and optoelectronic lighting devices.

### BACKGROUND

Applications such as a flashlight in mobile telephones, for example, require an LED package having an optical unit to distribute the light correspondingly in the target region of the camera. If an optical unit is shaped by a cavity (no additional optical unit) in the plastics material of the package, the reflection is too diffuse to achieve a defined and efficient emission necessary for the application. If the (LED) light source only has a diffusely reflective reflector cavity, an additional optical element is, therefore, required at any rate.

An optical component such as a Fresnel lens or a reflector, for example, is generally fixed on the substrate by an additional process step such as adhesive bonding, for example. Problems often arise in achieving sufficient mechanical stability. In the application, the LED module is often subjected to high mechanical forces/stresses (shear forces, bending forces) that can result in the optical unit becoming detached.

### SUMMARY

We provide a method of producing an optoelectronic light device including providing a carrier on which is arranged at least one light-emitting diode including a surface that emits light during operation of the light-emitting diode, carrying out an injection molding process to encapsulate the light-emitting diode by molding as far as the light-emitting surface such that a molded housing is formed within which the light-emitting diode is encapsulated by molding, wherein the light-emitting surface remains at least partly free, shaping a reflector that reflects light emitted by the light-emitting surface during the injection molding process such that the reflector is formed integrally with the housing, at least partly masking the light-emitting surface, coating the reflector with a light-reflecting layer after the masking, and demasking the light-emitting surface after the coating.

We also provide an optoelectronic light device including a carrier on which is arranged at least one light-emitting diode including a surface that emits light during operation of the light-emitting diode, wherein a molded housing is formed within which the light-emitting diode is encapsulated by molding, wherein the light-emitting surface is formed such that it remains at least partly free, a reflector that reflects light emitted by the light-emitting surface is formed integrally with the housing, and the reflector is coated by a light-reflecting layer.

### BRIEF DESCRIPTION OF THE DRAWINGS

FIGS. 1 to 12 show a production step of a method of producing an optoelectronic light device.

FIG. 13 shows a flow diagram of a method of producing an optoelectronic lighting device.

FIG. 14 shows a side view of a mask.

FIG. 15 shows a plan view of the mask from FIG. 14.

FIG. 16 shows a production step corresponding to the production step shown in FIG. 1 of a method of producing an optoelectronic light device using a flip-chip.

FIG. 17 shows a production step corresponding to the production step shown in FIG. 2 of the method of producing an optoelectronic light device using a flip-chip.

### LIST OF REFERENCE SIGNS

101 Carrier
103 First section
105 Section section
107 Light-emitting diode
109 Carrier element
111 Light-converting layer
113, 115 Tools
117 Film
119 Bond wire
121 Light-emitting surface
201 Housing
203 Reflector
301 Mask
303, 305 Limbs
307 Crossbar
501 Film
601 Photoresist
801 Vacuum chamber
803 Metal sample
805 Evaporated metal
807 Metal layer
901 Metal target
903 Sputtering parts
905 Direction of movement
907 Sputtered metal
909 Metal layer
1001 Optoelectronic lighting device
1003 Light-reflecting layer
1101 Optoelectronic lighting device
1103 Bond pad
1201 Optoelectronic lighting device
1203 Plated-through hole
1205 Further plated-through hole
1301 Providing
1305 Carrying out
1307 Shaping
1309 Masking
1311 Coating
1313 Demasking
1601 Leadframe
1603 Electrically conducting first contact section
1605 Electrically conducting second contact section
1607 Light-emitting diode chip
1609 Underside of the light-emitting diode chip
1611 Top side of the light-emitting diode chip
1613 Carrier element
1615 Underside of the carrier element
1617 Top side of the carrier element
1619 Light-converting layer
1621 Underside of the leadframe
1623 Top side of the leadframe
1701 Cavity
1703 Lateral surface of the cavity
1705 Bottom region of the cavity

### DETAILED DESCRIPTION

Our method of producing an optoelectronic lighting device may comprise the following steps:
providing a carrier on which is arranged at least one light-emitting diode comprising a surface that is light-emitting during operation of the light-emitting diode,
carrying out an injection molding process to encapsulate the light-emitting diode by molding as far as the light-emitting surface such that a molded housing is formed within which the light-emitting diode is encapsulated by molding, wherein the light-emitting surface remains at least partly, in particular completely, free,
shaping a reflector to reflect light emitted by the light-emitting surface during the injection molding process such that the reflector is formed integrally with the housing,
at least partly masking the light-emitting surface,
coating the reflector with a light-reflecting layer after the masking, and
demasking the light-emitting surface after the coating.

Our optoelectronic lighting device may comprise:
a carrier on which is arranged at least one light-emitting diode comprising a surface that is light-emitting during operation of the light-emitting diode, wherein
a molded housing is formed within which the light-emitting diode is encapsulated by molding, wherein the light-emitting surface is formed such that it remains at least partly, in particular completely, free, wherein
a reflector that reflects light emitted by the light-emitting surface is formed integrally with the housing, wherein
the reflector is coated by a light-reflecting layer.

We thus provide the concept, in particular, of shaping the reflector jointly with the housing during the injection molding process such that a reflector that is integral with the housing is formed. This makes it possible to bring about the technical advantage, for example, that an additional process step such as adhesive bonding, for example, can be dispensed with. A further advantage of an integral reflector resides in high mechanical stability, in particular.

Coating the reflector with the light-reflecting layer brings about the technical advantage, in particular, that an efficient and in particular a directional reflection of the light is made possible. As a result, for example, a luminous efficiency of the lighting device can be increased.

The fact that the light-emitting surface is at least partly masked before the coating brings about the technical advantage, in particular, that the masked region of the light-emitting surface is not coated with the light-reflecting layer. As a result, advantageously, after demasking, light can continue to be emitted by the light-emitting surface.

The fact that the light-emitting diode is encapsulated by molding as far as the light-emitting surface before the reflector is coated with the light-reflecting layer brings about the technical advantage, in particular, that the light-emitting diode itself is not coated by the light-reflecting layer. As a result, for example, short circuits or an electromigration can advantageously be avoided.

The injection molding process may comprise film assisted injection molding. This brings about the technical advantage, in particular that the housing can be produced efficiently. In particular, by film assisted injection molding, it is possible to efficiently produce a multiplicity of optoelectronic lighting devices simultaneously.

For example, a plurality of light-emitting diodes may be arranged on a common carrier. For each light-emitting diode a respective reflector may be molded integrally with the housing in accordance with the explanations given above and/or below. The plurality of light-emitting diodes may then be at least partly masked. To put it more precisely, the light-emitting surface may at least partly be masked. The individual reflectors may then be coated by a light-reflecting layer after masking, wherein, the light-emitting surfaces may then be demasked. In particular, the light-emitting diodes with their associated coated reflector may be singulated from the common carrier. Explanations in association with an individual light-emitting diode analogously apply to examples comprising a plurality of individual light-emitting diodes arranged on a common carrier. Therefore, the injection molding process, the coating process, the masking, coating and demasking are preferably carried out jointly for the light-emitting diodes on the common carrier.

The light-emitting surface may be completely masked.

At least partly masking, in particular completely masking, comprises applying a mechanical mask, in particular a film, or applying a lithographic mask to the light-emitting surface. Applying a mechanical mask has the advantage, in particular, that an efficient masking of the light-emitting surface can be brought about as a result. In particular, such a mechanical mask can be used repeatedly. The film is tailored in particular specifically for the light-emitting surface, that is to say has, for example, a surface area corresponding to the light-emitting surface.

Applying the lithographic mask has the advantage, in particular, that the light-emitting surface can be masked by known lithographic processes. For example, for the purpose of masking it is provided that a photoresist as lithographic mask is applied to the light-emitting surface.

Coating may comprise a chemical and/or a physical coating process. This brings about the technical advantage, in particular, that coating can be carried out by efficient and effective coating processes. By way of example, a chemical process comprises a chemical vapor deposition (CVD). A physical coating process comprises a physical vapor deposition (PVD), for example. By way of example, a physical vapor deposition comprises a thermal evaporation and/or an electron beam evaporation and/or a laser beam evaporation and/or an arc evaporation and/or a molecular beam epitaxy and/or a sputtering and/or an ion beam assisted deposition and/or an ion plating and/or an ICBD process (“Ionized Cluster Beam Deposition”), that is to say an ion assisted physical vapor deposition method.

Before the coating, a primer layer may be applied to the reflector. Providing such a primer layer has the technical advantage, in particular, that a surface of the reflector can thereby be smoothed which can then bring about an increase in reflectivity of the light-reflecting layer. In particular, the primer layer has the effect that an adhesion of the light-reflecting layer is improved. The primer layer comprises a resist, for example.

A protective layer may be applied to the light-reflecting layer. This brings about the technical advantage, in particular, that the light-reflecting layer can be protected against harmful external influences. By way of example, the protective layer can be an anti-corrosion protective layer. That is to say, therefore that the protective layer can bring about protection against corrosion. By way of example, the protective layer comprises silicon dioxide (SiO₂) and/or HMDS (hexamethyldisilazane: C₆H₁₉NSi₂).

The protective layer can be applied by a chemical and/or a physical coating process. These coating processes can be, for example, the coating processes mentioned above.

The light-reflecting layer may be patterned. This brings about the technical advantage, in particular, that a defined emission characteristic of the reflective light can be brought about.

The light-reflecting layer may be electrically conductive, wherein a plated-through hole is formed through the housing to an electrode of the light-emitting diode by a procedure in which a cutout running through the housing to the electrode is coated during the coating by the light-reflecting layer.

This brings about the technical advantage, in particular, that the light-reflecting layer performs a double function: first, a light-reflecting function and second a plated-through hole function. An efficient utilization of the light-reflecting layer is brought about as a result. In particular, it is thus advantageously made possible that the electrode can be electrically contacted by the light-reflecting layer.

The carrier may comprise two sections electrically insulated from one another, wherein the light-emitting diode is arranged on one of the two sections, wherein a further plated-through hole is formed through the housing to the other of the two sections by a procedure in which a cutout running through the housing to the other section is coated during the coating by the light-reflecting layer, wherein the two plated-through holes electrically connect to one another by the applied light-reflecting layer such that an electrical connection is formed between the electrode and the other section.

This brings about the technical advantage, in particular, that here, too, the light-reflecting layer has a double function: a light-reflecting function and a plated-through hole function. That is to say, therefore, that the light-reflecting layer forms an electrical connection between the electrode and the other section. Consequently, an electrical contacting of the electrode of the light-emitting diode can thus be brought about by the other section.

That is to say, therefore, that the housing has one or two of such cutouts formed before the coating process, that is to say before the step of coating the reflector. By way of example, the cutouts (or the cutout) can be drilled or formed mechanically, for example, by a laser. In particular, the cutouts (or the cutout) are already formed during the injection molding process.

In the context of the coating process, the cutouts (or the cutout) are (is) likewise coated with the light-emitting layer which is electrically conductive or electrically conducting in this example. Consequently, an electrical connection between the electrode of the light-emitting diode and the first section thus forms by the two plated-through holes and the light-emitting layer applied on the reflector.

That is to say, therefore, that the two plated-through holes electrically connect by the reflector coating.

A plated-through hole can be designated as a via, in particular.

The electrode of the light-emitting diode is, for example, an anode or a cathode of the light-emitting diode.

The light-reflecting layer may be electrically conductive.

The light-reflecting layer may be a metal layer, in particular an aluminium layer or a silver layer, or comprises such a metal layer. As a result of the provision of a metal layer, in particular an electrical conductivity of the light-reflecting layer is produced. Second, a metal layer generally has a particularly good light-reflecting property.

Light-reflecting means, in particular, that the light-reflecting layer has a reflectivity to the light emitted by the light-emitting surface during operation of the light-emitting diode of greater than 90%, in particular greater than 95%, preferably greater than 99%.

The carrier may be formed as a leadframe such that the housing is formed as a QFN housing.

In this case, the abbreviation “QFN” stands for “Quad Flat No Leads Package,” which can also be designated as “Micro Leadframe MLF.” A leadframe denotes, in particular, a solderable metallic lead carrier in the form of a frame or comb. In German, a leadframe can be designated as a “Anschlussrahmen” (“connection frame”).

The reflector may be coated by a primer layer on which the light-reflecting layer is applied.

A protective layer may be applied to the light-reflecting layer.

The light-reflecting layer may be patterned.

The light-reflecting layer may be electrically conductive, wherein a plated-through hole is formed through the housing to an electrode of the light-emitting diode by a procedure in which a cutout running through the housing to the electrode is coated by the light-reflecting layer.

The carrier may comprise two sections electrically insulated from one another, wherein the light-emitting diode is arranged on one of the two sections, a further plated-through hole is formed through the housing to the other of the two sections by a procedure in which a cutout running through the housing to the other section is coated by the light-reflecting layer, and the two plated-through holes electrically connect to one another by the light-reflecting layer such that an electrical connection is formed between the electrode and the other section.

Device features emerge analogously from corresponding method features, and vice versa. That is to say, therefore, that correspondingly given explanations concerning the method also apply to the device, and vice versa.

The optoelectronic lighting device may be produced by the method of producing an optoelectronic lighting device.

The light-emitting diode may be formed as a light-emitting diode chip (LED chip). The light-emitting diode chip may be a flip-chip, for example. That is to say that the LED chip electrically contacts or is electrically contactable exclusively from its underside. By way of example, the light-emitting diode chip electrically contacts or is contactable both from its underside and from its top side. An electrical contacting is brought about or formed by a bond wire, in particular.

The light-emitting diode is electrically contacted from its underside, for example, by one section. By way of example, a cathode of the light-emitting diode is contacted from below.

The light-emitting diode is electrically contacted from its top side, for example, by the other section. By way of example, an anode of the light-emitting diode is contacted from above.

A carrier element may be arranged on the light-emitting diode, a wavelength-converting layer being applied on the carrier element. The wavelength-converting layer converts electromagnetic radiation (for example, light) having a first wavelength or a first wavelength range emitted by the light-emitting diode during operation into light having a second wavelength or a second wavelength range. By way of example, the light-converting layer comprises a phosphor.

The wavelength-converting layer may be arranged directly on the light-emitting diode, that is to say without a carrier element.

Demasking may comprise mechanically and/or chemically removing the mask from the light-emitting surface.

An injection molding compound for the injection molding process may comprise a plastic. The housing thus comprises a plastic.

The carrier may be concomitantly encapsulated by molding into the housing. That is to say that the carrier is encapsulated by molding within the housing, wherein, electrical connections of the carrier remain at least partly free, that is to say are not concomitantly encapsulated by molding. An electrical contacting of the light-emitting diode is advantageously brought about by the electrical connections. By way of example, the two sections each comprise an electrical connection that remains free.

A self-aligning lithographic photo-process may comprise the following steps: the light-emitting surface is coated by negative resist. The light-emitting diode is switched on for a predetermined exposure time such that the light-emitting diode exposes the negative resist. The exposed negative resist is subsequently developed. In this case, the developed negative resist will remain on the light-emitting surface and acts as lithographic mask. After development, the light-reflecting layer is applied. After the light-reflecting layer has been applied, the developed exposed negative resist is removed.

The reflector may form a cavity. The light-emitting surface is arranged in a bottom region of the cavity, for example. A lateral surface (which can also be designated as a cavity surface) of the cavity may be coated with the light-reflecting layer.

After the process of shaping the reflector, the light-emitting surface may be at least partly, in particular completely, masked.

Masking the light-emitting surface is preferably carried out before coating the reflector with the light-reflecting layer.

The above-described properties, features and advantages of and the way in which they are achieved will become clearer and more clearly understood in association with the following description of the examples explained in greater detail in association with the drawings.

Identical reference signs may be used hereinafter for identical features.

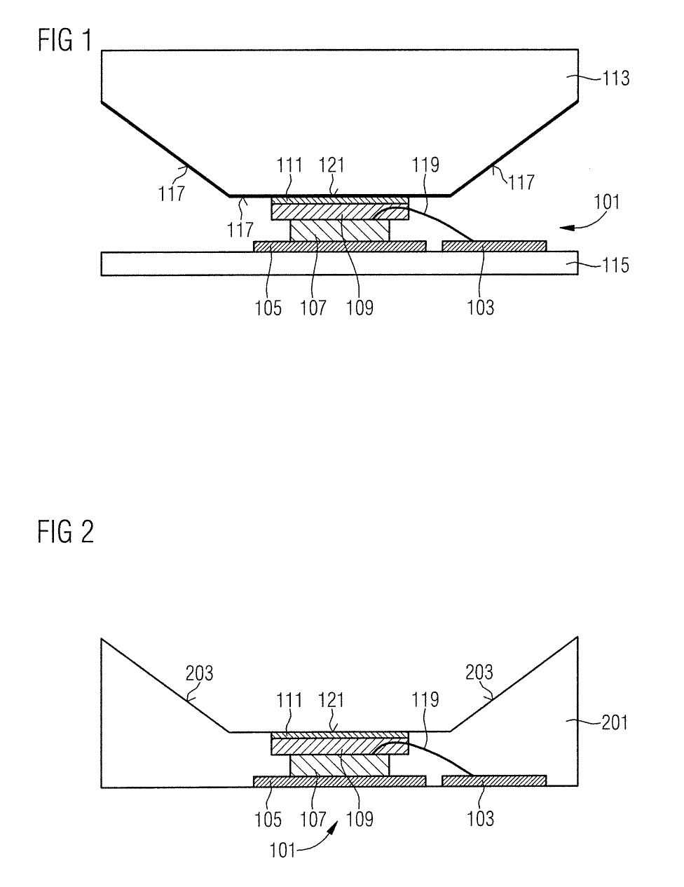

FIG. 1 shows a carrier 101 formed, for example, as a leadframe. The carrier 101 comprises two sections electrically insulated from one another: a first section 103 and a second section 105. A light-emitting diode 107 is arranged on the section 105, the light-emitting diode being formed, for example, as a light-emitting diode chip. A carrier element 109 is arranged on the light-emitting diode 107, a wavelength-converting or light-converting layer 111 being applied on the carrier element 109. The wavelength-converting layer 111 converts light having a first wavelength or a first wavelength range emitted by the light-emitting diode 107 into light having a second wavelength or a second wavelength range. By way of example, the light-converting layer 111 comprises a phosphor. A surface 121 of the light-converting layer 111 facing away from the second section 105 thus emits converted light during the operation of the light-emitting diode 107. Therefore, the surface 121 can be designated as a light-emitting surface. Since the light-converting layer 111 is arranged by its surface 121 on the carrier element 109, which is itself arranged on the light-emitting diode 107, the light-emitting diode 107 thus comprises a light-emitting surface, the surface 121.

Furthermore, a bond wire 119 is provided, which electrically contacts the first section 103 with an electrode (not shown in detail) of the light-emitting diode 107. By way of example, the bond wire 119 contacts an anode of the light-emitting diode 107. A further electrode, which can also be designated as a counterelectrode, for example, a cathode of the light-emitting diode 107 is electrically contacted by the second section 105. That is to say, therefore, that the second section 105 contacts the light-emitting diode 107 from below. The first section 103 contacts the light-emitting diode 107 from above by the bond wire 119.

FIG. 1 furthermore shows two injection molding tools 113, 115, wherein the injection molding tool 113 has a film 117 facing the light-emitting diode 107 and the carrier 101. The carrier 101 comprising the light-emitting diode 107 is situated between the two tools 113, 115. The tool 113 is displaced in the direction of the carrier 101 such that the film 117 is led as far as the light-emitting surface 121. That is to say that, in an end state, the film 117 contacts the light-emitting surface 121.

An injection molding process is then provided such that an injection molding compound is injected into an interspace between the two tools 113, 115. As a result, a housing 201 (cf. FIG. 2) can be molded, wherein all elements shown in FIG. 1 are encapsulated by molding within the housing 201, apart from the light-emitting surface 121, which thus remains at least partly free, in particular completely.

That is to say, therefore, that the carrier 101 with its two sections 103, 105, the light-emitting diode 107, the carrier element 109, the light-converting layer 111 apart from the light-emitting surface 121 and the bond wire 119 are encapsulated by molding, that is to say are encapsulated by molding in the molded housing 201.

FIG. 2 shows the correspondingly molded housing 201. The latter has a reflector 203 shaped in a manner corresponding to the shape of the tool 113. The reflector 203 is still uncoated. The light-emitting surface 121 remained free and was therefore not encapsulated by molding in the housing 201.

An injection molding process such as has been described above in association with FIGS. 1 and 2 can be designated, for example, as film assisted injection molding. Injection molding can also be designated as “molding.” That is to say, therefore, that the housing 201 is a molded housing. The individual elements are thus encapsulated by molding.

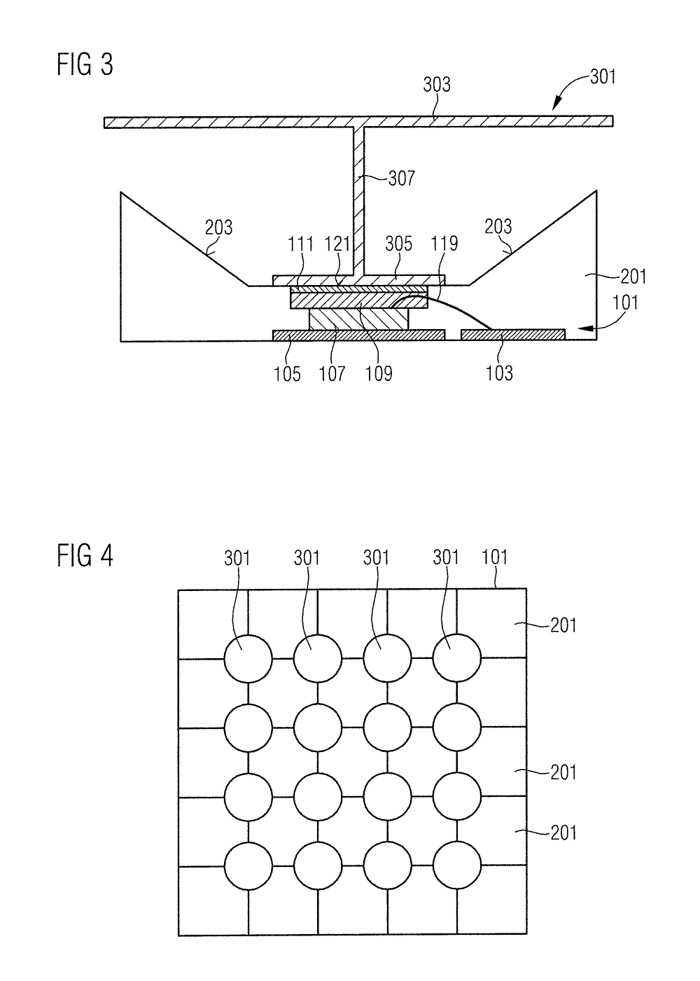

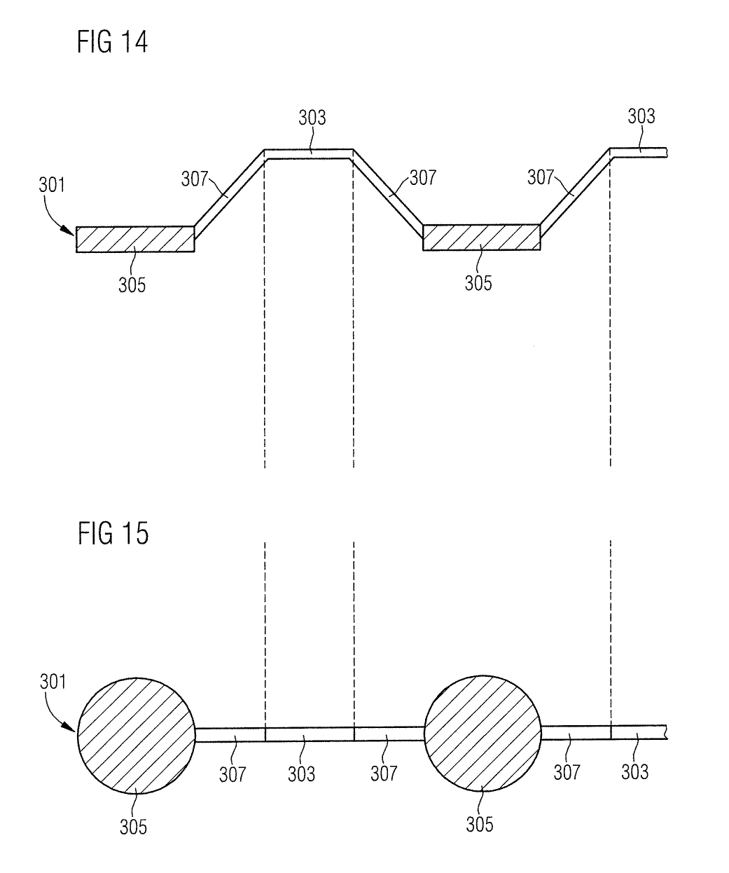

FIG. 3 shows by way of example one example of masking the light-emitting surface 121. For this purpose, provision is made of a mechanical mask 301 having two limbs 303, 305 running parallel to one another and connected by a crossbar 307 in a manner similar to an H-shape. In this case, the limb 305 is shorter than the limb 303 having, for example, a length corresponding to the width of the housing 201. The limb 305 has, for example, a surface area larger than the surface 121 or corresponding to the surface 121. This is because the limb 305 of the mask 301 is intended to, and will, mask the surface 121. Consequently, the element 305 is a functional element since it encompasses the function of masking. The limb 303 and the crossbar 307 may be transparent or at least partly transparent. The limb 303 and the crossbar 307 have, in particular, a mounting function for the limb 305. A specific size and/or a specific length generally need not be predefined for the limb 303 and the crossbar 307 as long as they hold the limb 305. A further example of a mask 301 is shown in FIGS. 14 (side view) and 15 (plan view). The two limbs 303 and 305 are arranged parallel to one another in an offset fashion and connect by obliquely running crossbars 307. The limb 305 has, in particular, a size corresponding to the light-emitting surface 121.

For the purpose of masking, therefore, the limb 305 of the mask 301 is applied to the light-emitting surface 121 such that the limb 305 masks the light-emitting surface 121. In an example not shown, the limb 305 may be formed such that it only partly masks the light-emitting surface 121. In such a case, the non-masked regions of the light-emitting surface 121 would then likewise be coated in a subsequent coating step. This may be desired for design reasons, for example.

FIG. 4 shows an example in which a plurality of light-emitting diodes 107 in accordance with FIG. 1 are arranged on a common carrier 101 on respective first and second sections 105, 103. That is to say that an injection molding process such as was described above can then likewise be carried out for such a common carrier. A dedicated housing 201 is then correspondingly formed for each light-emitting diode 107, in which case these housings 201 have not yet been singulated. In such an example, for example, a mechanical mask in the form of a metal array is then provided, that is to say a mask 301 having a multiplicity of limbs 305 to mask the respective light-emitting surfaces 121. FIG. 4 shows a plan view of such a common carrier 101, illustrated in a simplified manner.

FIG. 5 shows a further possibility for masking the light-emitting surface 121. A film 501 is provided, which can also be designated as a film mask. The film 501 is applied to the light-emitting surface 121.

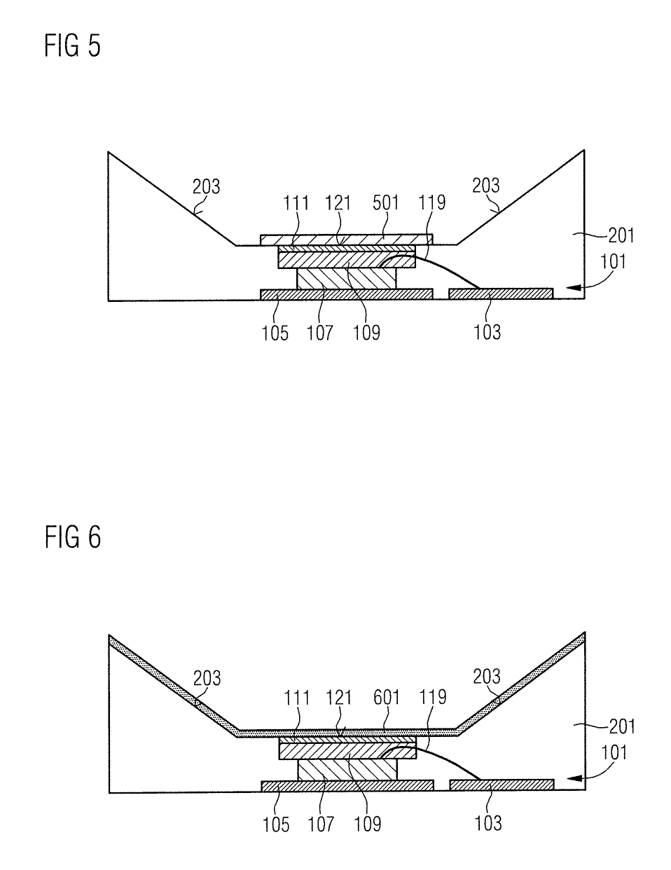

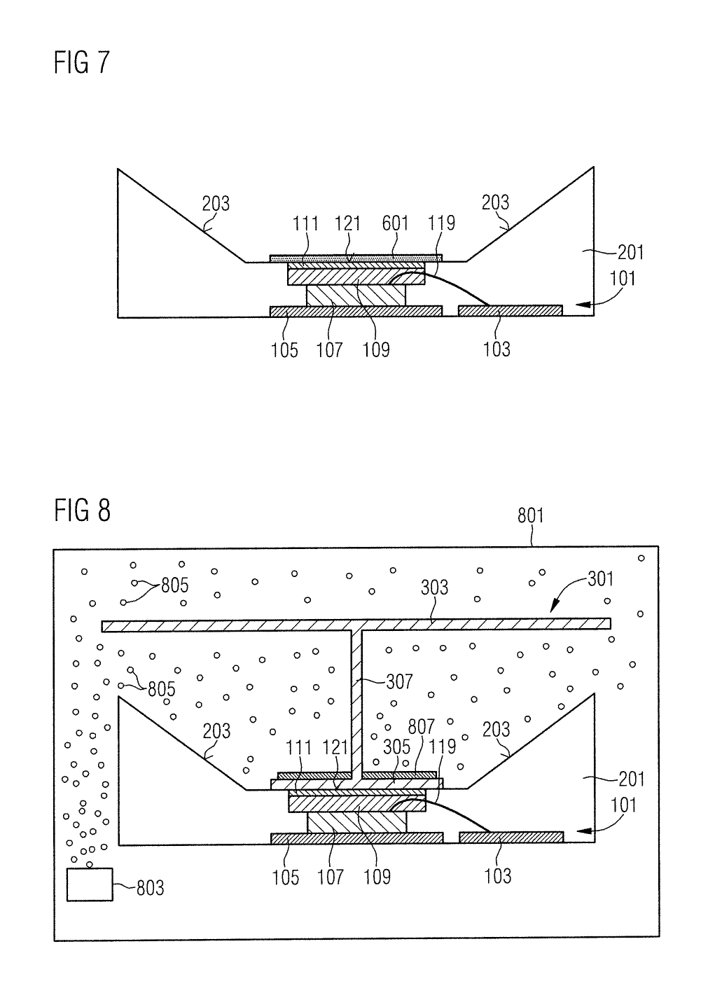

FIG. 6 shows a further possibility for masking the light-emitting surface. In accordance with this example, a photoresist 601 is applied to the reflector 203 and the light-emitting surface 121. The photoresist is patterned and, in accordance with FIG. 7, stripped away only from the reflector 203. That is to say that the photoresist 601 still covers the light-emitting surface 121 and, as shown in FIG. 7, also a region outside the light-emitting surface 121. How much the photoresist 601 is intended ultimately to mask can be effected or set by lithographic processes. The photoresist 601 can thus also be designated as a lithographic mask 601.

A self-aligning lithographic photo-process may comprise the following steps: the light-emitting surface is coated by a negative resist. The light-emitting diode is switched on for a predetermined exposure time such that the light-emitting diode exposes the negative resist. The exposed negative resist is subsequently developed. In this case, the developed negative resist will remain on the light-emitting surface and acts as a lithographic mask. After development, the light-reflecting layer is applied. After the light-reflecting layer has been applied, the developed exposed negative resist is removed.

FIG. 8 shows one possibility as to how the reflector 203 can be coated by a light-reflecting layer. In this regard, the arrangement shown in FIG. 3 is introduced into a vacuum chamber 801. A metal sample 803 to be evaporated, for example, an aluminium sample is situated within the vacuum chamber 801. A chemical vapor deposition process (CVD process) is then carried out in a vacuum to evaporate the metal sample 803. The evaporated metal is illustrated by way of example by circles having the reference sign 805. The evaporated metal 805 will therefore be deposited onto the reflector 203 such that the reflector 203 is coated by the evaporated metal 805. A metal layer thus forms on the reflector 203. The metal layer, in particular the aluminium layer, is a light-reflecting layer.

If the mask 301 were not present, that is to say if the light-emitting surface 121 were not masked, then evaporated metal 805 would also be deposited onto the surface 121. However, since the light-emitting surface 121 is masked by the mask 301, no light-reflecting layer can form in the masked region, that is to say in particular on the light-emitting surface 121. Instead, a metal layer 807 forms on the limb 305 of the mask 301.

Applying or depositing or coating by a metal layer can generally also be referred to as a metallization.

In an example not shown, after the metallization, a protective layer, for example, HMDS or SiO₂, is applied to the metallization.

Before the metallization, a primer layer (for the purpose of smoothing and/or adhesion) may be applied to the reflector 203. The primer layer is a resist layer, for example.

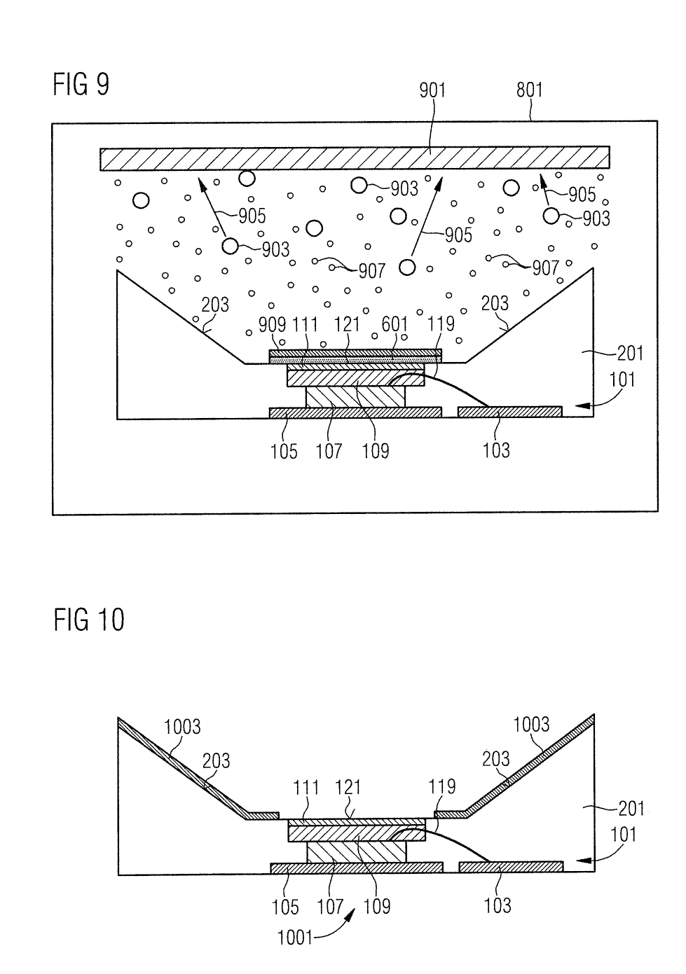

FIG. 9 shows another possibility for a coating. In accordance with this example, the arrangement shown in FIG. 7 is introduced into a vacuum chamber 801 where a so-called “metal target” 901, for example, an aluminium target, that is to say a metal sample, in particular an aluminium sample, is situated. The metal target 901 is sputtered or acted on by sputtering elements 903. That is to say, therefore, that the sputtering elements 903 are moved in the direction of the metal target 901 and impinge thereon for the purpose of a sputtering process. The direction of movement of the sputtering parts or sputtering elements 903 is illustrated symbolically by an arrow having the reference sign 905. On account of the sputtering process, metal atoms and/or metal molecules detach from the metal target 901 and metallize the reflector 203. Since the light-emitting surface 121 is masked by the photoresist 601, the light-emitting surface 121 is not metallized.

FIG. 10 shows an optoelectronic lighting device 1001 after the mask was removed after the process of coating the reflector 203. Depending on the type of mask, mechanical or lithographic mask, the step of demasking the light-emitting surface 121 comprises a mechanical or chemical processing step. That is to say, therefore, that, according to the mask used, the mask is removed chemically or mechanically from the light-emitting surface 121.

The light-reflecting layer formed on account of the metallization on the reflector 203 is provided with the reference sign 1003 here.

The light-reflecting layer 1003 may be patterned. This advantageously brings about a defined emission characteristic of the reflected light.

On account of the masking of the light-emitting surface 121, the light-emitting surface 121 is free of a light-reflecting layer after metallization. That is to say, therefore, that no light-reflecting layer is situated on the light-emitting surface 121.

In examples not shown, a CVD process in accordance with FIG. 8 is also carried out for an arrangement in accordance with FIG. 5 or 7. Correspondingly, in an example not shown, a sputtering process is carried out for the arrangements shown in FIGS. 4 and 5.

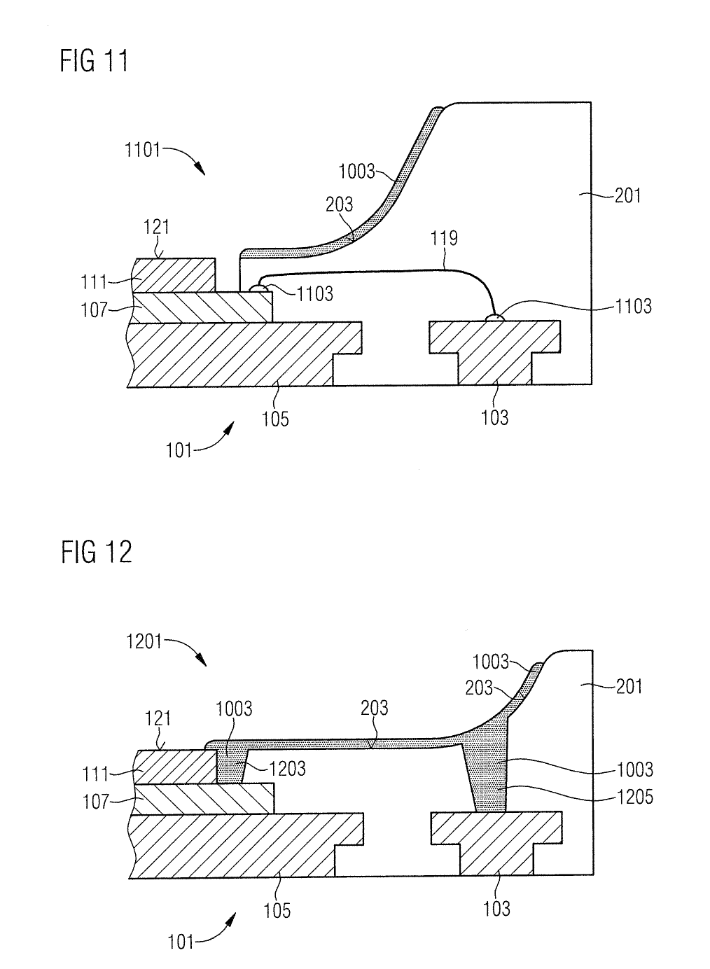

FIG. 11 shows a further optoelectronic lighting device 1101 in a cut-away sectional illustration.

The bond wire 119 can be seen, which, by a respective bond pad 1103, electrically connects an electrode of the light-emitting diode 107 to the first section 103. That is to say, therefore, that a bond pad 1103 is situated on the first section 103. The second bond pad 1103 is situated on the light-emitting diode 107, in particular on a top side of the chip. That is to say, therefore, that, for example, the anode of the light-emitting diode 107 electrically connects to the first section 103 by the bond wire 119. According to one example, a wire ball can be provided instead of a bond pad. This is the case, therefore, in particular depending on what electrical connection technique is provided.

FIG. 12 shows a further optoelectronic lighting device 1201.

In this example, the bond wire 119 can be dispensed with. The electrical contacting of the electrode, for example, of the anode, of the light-emitting diode 107 with the first section 103 is formed as follows.

A plated-through hole 1203 is provided, which runs through the housing 201 as far as the electrode of the light-emitting diode 107. The plated-through hole 1203 is formed by a corresponding cutout running through the housing 1205 to the electrode of the light-emitting diode 107. The cutout was likewise coated with the light-reflecting layer, for example, the metal layer during the coating process.

Furthermore, a further plated-through hole 1205 is formed, which runs through the housing 201 to the first section 103. Here, too, the plated-through hole 1205 is formed from a cutout running through the housing 201 to the first section 103 and was likewise coated on account of the coating process by the light-reflecting layer.

That is to say, therefore, that the housing 201 has two of such cutouts formed before the coating process, that is to say before the step of coating the reflector. By way of example, the cutouts can be drilled or formed mechanically, for example, by a laser. In particular, the cutouts are already formed during the injection molding process.

In the context of the coating process, the cutouts are likewise coated with the light-emitting layer, which is electrically conductive or electrically conducting in this example. Consequently, an electrical connection thus forms between the electrode of the light-emitting diode 107 and the first section 103 by the two plated-through holes 1203, 1205 and the light-emitting layer 1003 applied on the reflector 203.

That is to say, therefore, that in this example in accordance with FIG. 12, the two plated-through holes 1203, 1205 electrically connect by the reflector coating.

A plated-through hole can be designated as a via, in particular.

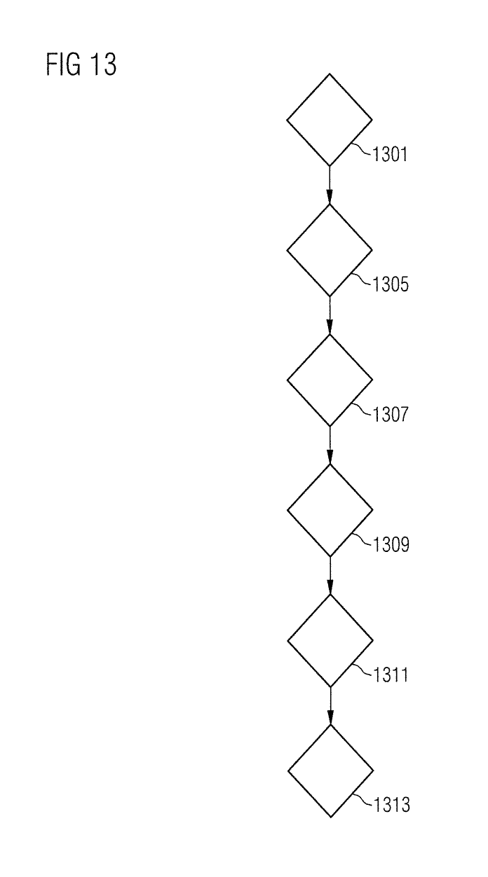

FIG. 13 shows a flow diagram of a method of producing an optoelectronic lighting device, comprising the following steps:
providing 1301 a carrier, on which is arranged at least one light-emitting diode comprising a surface that is light-emitting during operation of the light-emitting diode,
carrying out 1305 an injection molding process to encapsulate the light-emitting diode by molding as far as the light-emitting surface such that a molded housing is formed within which the light-emitting diode is encapsulated by molding, wherein the light-emitting surface remains at least partly free,
shaping 1307 a reflector to reflect light emitted by the light-emitting surface during the injection molding process such that the reflector is formed integrally with the housing,
at least partly masking 1309 the light-emitting surface,
coating 1311 the reflector with a light-reflecting layer after the masking, and
demasking 1313 the light-emitting surface after the coating.

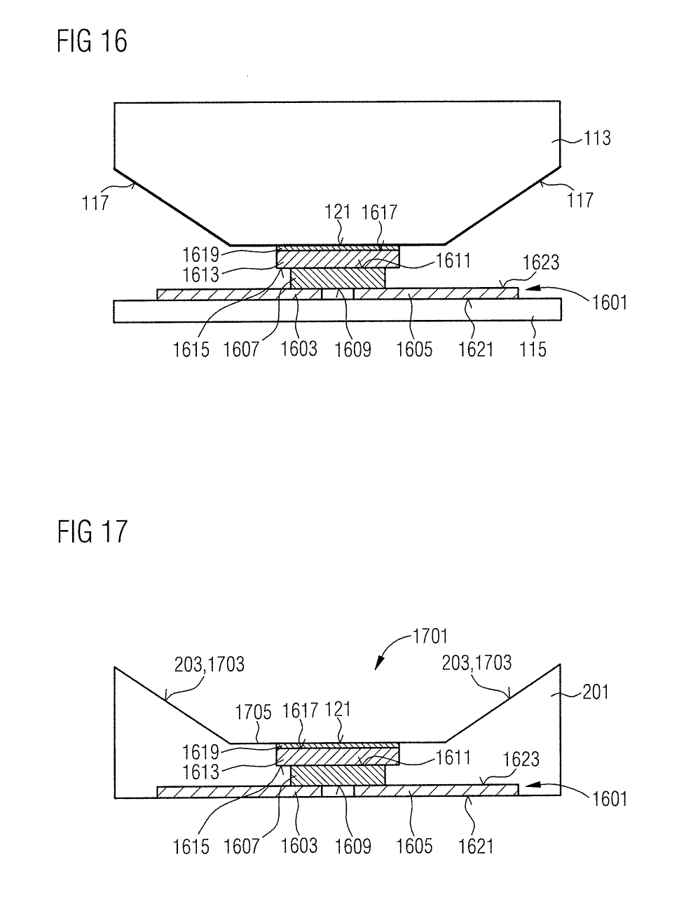

FIG. 16 shows a leadframe 1601. The leadframe 1601 is subdivided into an electrically conducting first contact section 1603 and an electrically conducting second contact section 1605, wherein the two contact sections 1603, 1605 are electrically insulated from one another. The leadframe 1601 has a top side 1623 and an underside 1621 situated opposite the top side 1623.

The light-emitting diode 1607 used for the method is a light-emitting diode chip of the flip-chip type. That is to say that the light-emitting diode chip 1607 is a flip-chip. That is to say that the light-emitting diode chip 1607 is electrically contacted exclusively from its underside 1609. For this purpose, two electrically conducting contact pads (not shown) are formed at the underside 1609 of the light-emitting diode chip 1607.

The light-emitting diode chip 1607 is arranged, for example, soldered by its underside 1609 on the respective top side 1623 of the two contact sections 1603, 1605 such that one of the two contact pads electrically contacts the first contact section 1603 and the other of the two contact pads electrically contacts the second contact section 1605. Consequently, the light-emitting diode chip 1607 is electrically contacted from its underside 1609 by the two contact sections 1603, 1605.

A carrier element 1613 is arranged on a top side 1611 of the light-emitting diode chip 1607, the top side being situated opposite the underside 1609, the carrier element being at least partly transparent to electromagnetic radiation emitted by the light-emitting diode chip 1607.

The carrier element 1613 has an underside 1615 and a top side 1617 situated opposite the underside 1615. The carrier element 1613 is arranged, for example, adhesively bonded, by its underside 1615 on the top side 1611 of the light-emitting diode chip 1607.

A light-converting layer 1619 is arranged on the top side 1617 of the carrier element 1613. A side 1621 or surface of the layer 1619 facing away from the top side 1617 of the carrier element 1613 emits converted light during the operation of the light-emitting diode chip 1607. Consequently, the surface 1621 can be designated as a light-emitting surface.

FIG. 16 furthermore shows two injection molding tools 113, 115, wherein the injection molding tool 113 has a film 117 facing the light-emitting diode chip 1607 and the leadframe 1601. The leadframe 1601 comprising the light-emitting diode chip 1607 is situated between the two tools 113, 115. The leadframe 1601 is arranged by its underside 1621 on the tool 115. The tool 113 is displaced in the direction of the leadframe 1601 such that the film 117 is led as far as the light-emitting surface 121. That is to say that, in an end state, the film 117 contacts the light-emitting surface 121.

An injection molding process is then provided such that an injection molding compound is injected into an interspace between the two tools 113, 115. As a result, a housing 201 (cf. FIG. 17) can be molded, wherein all elements shown in FIG. 16 are encapsulated by molding within the housing 201, apart from the light-emitting surface 121, which thus remains at least partly free, in particular remains completely free, and also the underside 1621 of the leadframe 1601.

That is to say, therefore, that the leadframe 1601 with its two contact sections 1603, 1605, the light-emitting diode chip 1607 and the light-converting layer 1619 apart from the light-emitting surface 121 and the underside 1621 of the leadframe 1601 are encapsulated by molding such that the corresponding elements are encapsulated by molding or embedded in the molded housing 201. The underside 1621 of the leadframe 1601 remains free of the injection molding compound. That is to say that the underside 1621 remains free, that is to say is not covered with injection molding compound.

FIG. 17 shows the correspondingly molded housing 201. The latter has a reflector 203 shaped according to the shape of the tool 113. The reflector 203 is still uncoated. The light-emitting surface 121 remained free and was therefore not encapsulated by molding in the housing 201.

An injection molding process such as has been described above in association with FIGS. 16 and 17 can be designated, for example, as film assisted injection molding. Therefore, that the housing 201 is a molded housing. The individual elements are thus encapsulated by molding.

The reflector 203 is formed as a cavity 1701, wherein a lateral surface 1703 of the cavity 1701 is coated with a light-reflecting layer in the further method, as was described in association with FIGS. 3 to 10. Such a cavity was also formed by the injection molding method as shown and described in association with FIGS. 1 and 2. For the sake of clarity, however, the cavity was not provided separately with its own reference sign. The explanations given in association with FIGS. 16 and 17 analogously apply to FIGS. 1 and 2.

The light-emitting surface 121 is arranged in a bottom region 1705 of the cavity.

The housing 201 (shown in FIG. 17) comprising the reflector 203 may be a cavity 1701 provided with a cavity wall 1703 forms a QFN (QFN: “Quad Flat No Leads”) package having an integrated reflector.

This disclosure therefore encompasses, in particular and inter alia, the concept of reflectively coating a cavity, formed by the reflector, the cavity being shaped by injection molding. That is to say, therefore, in particular, that according to one example, it is possible to reflectively coat cavity walls, that is to say provide a reflector of a light-emitting diode.

It is possible, in particular, to integrate the reflector directly into the LED housing by virtue of the reflector being formed integrally with the housing, wherein the correspondingly shaped reflector or cavity walls are reflectively coated.

The light-emitting diode may be arranged on the bare leadframe, that is to say the carrier. In particular, so-called “Wire Bonding” is carried out to electrically contact the light-emitting diode chip with the leadframe. In particular, it is provided that a light-converting layer is applied to the light-emitting diode. By way of example, a carrier element is provided, which comprises the light-converting layer, wherein the carrier element is applied to the light-emitting diode or to the light-emitting diode chip.

Injection molding, for example (transfer) molding, is provided. In an injection molding process, according to one example, the light-emitting diode chip and the light-converting layer are encapsulated by molding as far as the light-emitting surface. According to one example, at the same time as this encapsulation by molding, a reflector cavity is formed, that is to say that the reflector is shaped.

A selective metallization and/or reflector coating of the cavity, that is to say of the reflector, may then be carried out. Beforehand, however, the light-emitting surface is still at least partly, in particular completely, masked.

A singulation of the component assemblage may then take place.

Our concept has the advantage, in particular, that a reflector can be integrated directly into an LED package. The reflector is shaped by a film assisted transfer molding process step, for example, and then coated with aluminium and/or silver, for example, by segmented plating, for example. A primer layer and/or a protective layer may also be provided. The primer layer is applied to the reflector cavity before the segmented plating. The protective layer is applied to the metal layer, that is to say after the segmented plating. The coating brings about the technical advantage, in particular, that a metallized, specularly reflective surface comprising a directional reflection is formed.

During the plating process (for example, sputtering, CVD/PVD; Physical Vapor Deposition), one example omits the light-emitting surface or surface in the package. According to one example, this is effected by a corresponding masking, for example, by a lithographic mask and/or a mechanical mask.

Since the injection molding compound envelopes the light-emitting diode chip and the leadframe, that is to say generally the carrier, in an electrically insulating manner, it is advantageously possible to provide the cavity, that is to say the reflector, with a specularly reflective coating without risking short circuits, electromigration or the like. The metallization extends as far as the light-emitting surface according to one example or right onto the light-emitting surface according to one example.

That is not possible in conventional premold packages known heretofore because chip and leadframe contact pads are uncovered and the metallization of the reflector would produce short circuits. Moreover, on account of the pronounced surface topography, a patterning of the metallization (for example, by photographic steps) is very difficult, and so even a metallization with a safety distance with respect to the bottom of the cavity, that is to say of the reflector (that is to say the top side of the leadframe) is virtually impossible.

Our concept as described here, according to one example, can also be combined with a “Planar Interconnect (PI)-Technology” or else with a CPHF (Contact Planar High Flux) technology to contact and interconnect the light-emitting diode chip by the metallization/reflective coating of a lens (cf. FIG. 12, for example).

Our concept thus enables a light-shaping optical unit, the reflector, to be integrated entirely in the package. The coated reflector advantageously enables a directional reflection. That is to say, therefore, that, if appropriate, a further optical component can also be dispensed with. Moreover, the concept makes it possible to dispense with an additional process step such as adhesive bonding, for example. A further advantage resides, in particular, in a high mechanical stability associated with such an integrated concept.

The reflective coating may also be utilizable as an electrical contacting.

The “Off-state” appearance, that is to say the appearance in a switched-off operating state of the light-emitting diode, can be actively influenced by a configuration (geometry, patterning, color) of the metallization.

The light-reflecting layer, in particular the metallization, advantageously shields the actual housing material from radiation and in part from environmental influences (for example, corrosive gases).

Our concept thus furthermore encompasses, in particular, shaping the reflector in the QFN package by a film assisted molding process. At the same time, all the components on the substrate, that is to say the carrier, are encapsulated by molding such that only the light-emitting surface or surface remains free. The QFN package or QFN panel thus encapsulated by molding is masked. This can be realized or effected, for example, by a mechanical mask composed of metal, a specifically tailored film or by a lithographic mask. The panel or package is subsequently coated. According to one example, aluminium and/or silver are/is used as coating material. According to another example, before the metallization layer, a primer layer is applied to the plastic, that is to say the molded housing to smooth a surface, for example, which can bring about an increase in reflectivity, and/or to improve adhesion of the light-reflecting layer.

The metallization may be applied by a sputtering process or by a vacuum coating (CVD/PVD). According to one example, a protective layer, for example, HMDS or SiO₂, is applied to the metallization as protection against corrosion. The masks are then removed again (mechanically or chemically, depending on the process).

Our concept can be employed in particular in all applications in which light shaping by an optical unit is necessary or advantageous (increase in efficiency). One specific example is, for example, an application in a flash LED for mobile radio devices, for example, a smartphone. That is to say, therefore, that a flash LED for smartphones can be constructed according to the optoelectronic lighting device. In the case of lamps and luminaries, therefore, an efficiency can advantageously be increased by virtue of the fact that the light from the LED package can be directed onto the secondary optical units in a more targeted manner. This effect can advantageously also be used in automotive applications such as, for example, in headlights, or in LCD backlighting. Protection of housing material from radiation and environmental influences is also advantageous in these applications since a lifetime of the LED can thus be increased under certain circumstances.

Although our devices and methods have been more specifically illustrated and described in detail by the preferred examples, nevertheless this disclosure is not restricted by the examples disclosed and other variations can be derived therefrom by those skilled in the art without departing from the scope of protection of the appended claims.

This application claims priority of DE 10 2015 102 785.2, the subject matter of which is hereby incorporated by reference.

1. A method of producing an optoelectronic lighting device comprising:
providing a carrier on which is arranged at least one light-emitting diode comprising a surface that emits light during operation of the light-emitting diode,
carrying out an injection molding process to encapsulate the light-emitting diode by molding as far as the light-emitting surface such that a molded housing is formed within which the light-emitting diode is encapsulated by molding, wherein the light-emitting surface remains at least partly free,
shaping a reflector that reflects light emitted by the light-emitting surface during the injection molding process such that the reflector is formed integrally with the housing,
at least partly masking the light-emitting surface,
coating the reflector with a light-reflecting layer after the masking, and
demasking the light-emitting surface after the coating.

2. The method according to claim 1, wherein the injection molding process comprises film assisted injection molding.

3. The method according to claim 1, wherein at least partly masking comprises applying a mechanical mask or applying a lithographic mask to the light-emitting surface.

4. The method according to claim 1, wherein coating comprises a chemical and/or a physical coating process.

5. The method according to claim 1, wherein, before the coating, a primer layer is applied to the reflector.

6. The method according to claim 1, wherein a protective layer is applied to the light-reflecting layer.

7. The method according to claim 1, wherein the light-reflecting layer is patterned.

8. The method according to claim 1, wherein the light-reflecting layer is electrically conductive, and a plated-through hole is formed through the housing to an electrode of the light-emitting diode by a procedure in which a cutout running through the housing to the electrode is coated during the coating by the light-reflecting layer.

9. The method according to claim 8, wherein the carrier comprises two sections electrically insulated from one another, the light-emitting diode is arranged on one of the two sections, a further plated-through hole is formed through the housing to another of the two sections by a procedure in which a cutout running through the housing to the other section is coated during the coating by the light-reflecting layer, and the two plated-through holes electrically connect to one another by the applied light-reflecting layer such that an electrical connection is formed between the electrode and the another section.

10. The method according to claim 1, wherein the light-reflecting layer is a metal layer, an aluminium layer or a silver layer.

11. The method according to claim 1, wherein the carrier is formed as a leadframe such that the housing is formed as a QFN housing.

12. An optoelectronic lighting device comprising:
a carrier on which is arranged at least one light-emitting diode comprising a surface that emits light during operation of the light-emitting diode, wherein
a molded housing is formed within which the light-emitting diode is encapsulated by molding, wherein the light-emitting surface is formed such that it remains at least partly free,
a reflector that reflects light emitted by the light-emitting surface is formed integrally with the housing, and
the reflector is coated by a light-reflecting layer.

13. The optoelectronic lighting device according to claim 12, wherein the reflector is coated by a primer layer on which the light-reflecting layer is applied.

14. The optoelectronic lighting device according to claim 12, wherein a protective layer is applied to the light-reflecting layer.

15. The optoelectronic lighting device according to claim 12, wherein the light-reflecting layer is patterned.

16. The optoelectronic lighting device according to claim 12, wherein the light-reflecting layer is electrically conductive, and a plated-through hole is formed through the housing to an electrode of the light-emitting diode by a procedure in which a cutout running through the housing to the electrode is coated by the light-reflecting layer.

17. The optoelectronic lighting device according to claim 16, wherein the carrier comprises two sections electrically insulated from one another, the light-emitting diode is arranged on one of the two sections, a further plated-through hole is formed through the housing to another of the two sections by a procedure in which a cutout running through the housing to the other section is coated by the light-reflecting layer, and the two plated-through holes electrically connect to one another by the light-reflecting layer such that an electrical connection is formed between the electrode and the other section.

18. The optoelectronic lighting device according to claim 12, wherein the carrier is formed as a leadframe such that the housing is formed as a QFN housing.
